(19) United States
(12) Patent Application Publication
(10) Pub. No.: US 2006/0035400 A1
(43) Pub. Date: Feb. 16, 2006

(54) Apparatus of ion sensitive thin film transistor and method of manufacturing of the same

(75) Inventors: Yung Fu Wu, Zhonghe City (TW); Tzu Hsuan Tsai, Taichung City (TW)

Correspondence Address: BRUCE H. TROXELL, 5205 LEESBURG PIKE, SUITE 1404, FALLS CHURCH, VA, 22041, US

(73) Assignee: Industrial Technology Research Institute

(21) Appl. No.: 11/002,282

(22) Filed: Dec. 3, 2004

(30) Foreign Application Priority Data
Aug. 10, 2004 (TW) 93130475

(51) Int. Cl. H01L 21/00; H01L 23/58

(52) U.S. Cl. 438/49; 257/253

(57) ABSTRACT

The present invention discloses an apparatus of ion sensitive thin film transistor and method of manufacturing of the same. The apparatus of the invention, formed on a glass substrate, comprises an ion detector, formed on said glass substrate, including a plurality of ion sensitive transistors and a signal processor with display, also formed on said glass substrate, being coupled with said ion detector. The signal processor with display further comprises a circuit of signal processing, a driver circuit, and a display, wherein by means of the method of Low Temperature PolySilicon, i.e. LTPS technology, the invention integrates said ion detector and said signal processor with display on said glass substrate to become an tiny, light and thin apparatus with portable and disposable characteristics.

### 1. FIELD OF THE INVENTION

The present invention relates to an apparatus of ion sensitive thin film transistor and method of manufacturing of the same. More particularly, the invention relates to utilize Low Temperature PolySilicon, i.e. LTPS, processing to integrate ion sensitive transistors, electric control circuits and display panel on a glass substrate.

### 2. BACKGROUND OF THE INVENTION

The ISFET was first disclosed by P. Bergveld in 1970. The device is a product of applied electrochemistry and microelectronics, and has the function of ion selection and the properties of the FET. Referring to FIG. 1, the illustration describes the conventional ion sensitive transistor of the prior art. This ion sensitive transistor device is strictly different from the traditional ion selection electrode. P. Bergveld disclosed a FET, wherein the metal film set in the gate of traditional FET was removed. Furthermore, the device was immersed in electrolyte, wherein no reference electrode was present, on the other hand, there is a reference electrode added to determine the relative voltage between the electrolyte and the semiconductor substrate and then further to detect the current changed through channel.

With the combination of ion sensitive technology and microelectronic techniques, it is easy to minimize the devices of ion sensitive transistors or related and makes mass production for lowering the cost of manufacture. Meanwhile, since the ion sensitive transistors play a vital role in the modern inspection technology, a number of patents relating to ion sensitive transistors have been obtained, as summarized hereinafter:
(a) U.S. Pat. No. 6,236,075: disclosed ways to utilize a method of thermal evaporation or RF reactive sputtering to form a light shielding layer in order to reduce the influence of inaccuracy caused by light from circumstance.
(b) U.S. Pat. No. 5,319,226: disclosed a method to employ RF reactive sputtering to form a sensitive Ta₂O₅ membrane, 40 to 50 nanometer height, on the top of gate oxide layer in order to increase improvements of the sensitivity, stability, and yield of mass production.
(c) U.S. Pat. No. 6,617,190: disclosed a way using RF reactive sputtering to form a highly sensitive membrane, composed of a-WO₃, for acidic aqueous solution.
(d) U.S. Pat. No. 6,573,741: disclosed a sensitive membrane composed of hydrogenated amorphous silicon to detect the temperature of ion sensitive transistor, so as to reduce the error while testing.
(e) U.S. Pat. No. 4,180,771: disclosed an element of ion sensitive transistor whose sensitive area is not on the top of gate oxide, so as to prevent gate insulator and source/drains from being contaminated by solution.
(f) U.S. Pat. No. 4,773,970: disclosed a method using a specific polymer to form a polymeric membrane comprising a water-insoluble copolymer having ion exchange sites and has a glass transition temperature greater than about 80° C.

However, the conventional ion sensitive transistors are formed on the silicon substrates so that the final inspection products should couple additional devices such as PCB, LCD display, IC driver and so on with ion sensors.

In short, according to the previous disclosure, there are some drawbacks listed as following:
1. After the formation of ion sensitive transistors, those transistors should be coupled with the other devices to become an inspection apparatus. Consequently, it will induce a lot of cost and time consuming during production.
2. Because the inspection apparatus comprises sub-devices coupled with ion sensitive transistors, it will increase the bulk and thickness of said inspection apparatus.
   The disclosures of previous inventions are formed on silicon substrate. Although they are appropriate for mass production, the costs of the silicon substrates are very expensive.

### SUMMARY OF THE INVENTION

The main object of the present invention is to provide an apparatus of ion sensitive thin film transistor and method of manufacturing of the same, which combines the techniques of LTPS, panel driver IC, and ion sensors so as to achieve the objective of integration.

A further object of the invention is to provide an apparatus of ion sensitive thin film transistor and method of manufacturing of the same, wherein miniature, thinness, and low weight can be utilized.

Another object of the invention is to provide an apparatus of ion sensitive thin film transistor and method of manufacturing of the same, which forms the electronic elements on glass substrate by LTPS so as to lower cost.

For the purpose to achieve the objectives listed above, the present invention discloses an apparatus of ion sensitive thin film transistor and method of manufacturing of the same. The apparatus of the invention, formed on a glass substrate, comprises an ion detector, formed on said glass substrate, including a plurality of ion sensitive sensors and a signal processor with display, also formed on said glass substrate, coupling with said ion detector. The signal processor with display further comprises a circuit of signal processing, a driver circuit, and a display, wherein by means of the method of Low Temperature PolySilicon, i.e. LTPS, the invention integrates said ion detector and said signal processor with display on said glass substrate to become an tiny, light and thin apparatus with portable and disposable characteristics.

For the purpose to achieve the objectives listed above, the invention further provides a method of manufacturing an ion sensitive thin film transistor: (a) forming a buffer layer on a glass substrate; (b) forming an amorphous layer on said buffer layer and transforming said amorphous layer into poly-silicon layer with high temperature annealing; (c) forming a pair of source/drains on said poly-silicon layer; (d) forming a layer of gate oxide on said poly-silicon layer and opening contact holes on said layer of gate oxide opposite said pair of source/drains; (e) forming a metal layer on said layer of gate oxide and filling said contact holes for form a transistor; (f) forming a passivation layer with a probe area on said transistor; (g) covering said probe area with a sensitive membrane formed on said passivation layer.

The following descriptions of drawings and preferred embodiment could be taken in conjunction with the accompanying auxiliary drawings to specifically explain the present invention and facilitate examiner to examine the present invention.

### BRIEF DESCRIPTION OF THE DRAWINGS

The drawings, incorporated into and form a part of the disclosure, illustrate the embodiments and method related to this invention and will assist in explaining the detail of the invention.

FIG. 1 is a cross-sectional view of the conventional ion sensitive transistor.

FIG. 2a is a cross-sectional view of an embodiment according to principles the invention.

FIG. 2b is a cross-sectional view of another embodiment according to principles the invention.

FIG. 3 is a flow chart of the method to manufacture the ion sensitive thin film transistor according to the principles of the invention.

FIG. 4a through FIG. 4i are cross-sectional views illustrating the steps according to the method of the invention to manufacture ion sensitive thin film transistor.

FIG. 5 is a schematic view to illustrate the apparatus comprising ion sensitive detector and signal processor with display.

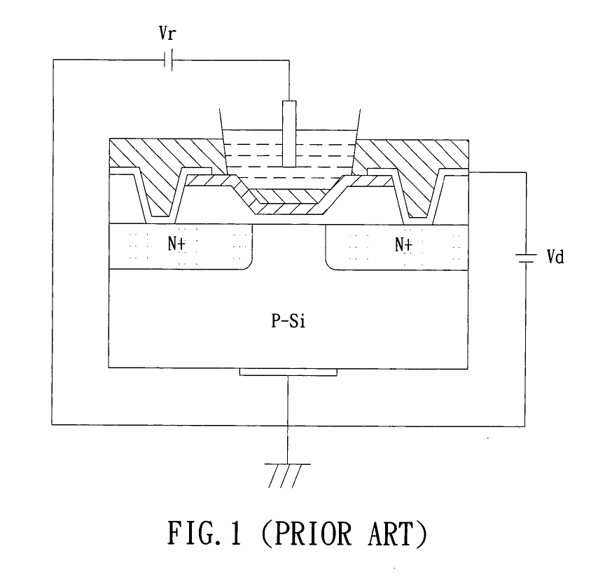

### DESCRIPTION OF THE PREFERRED EMBODIMENT

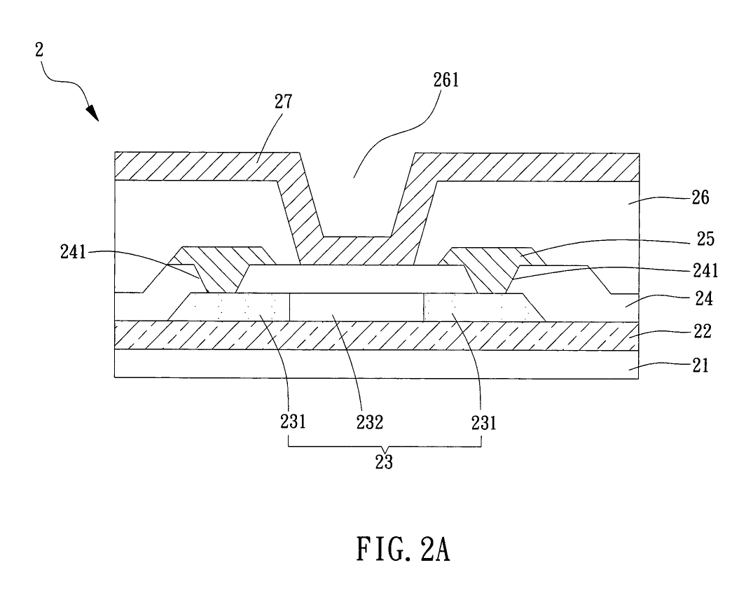

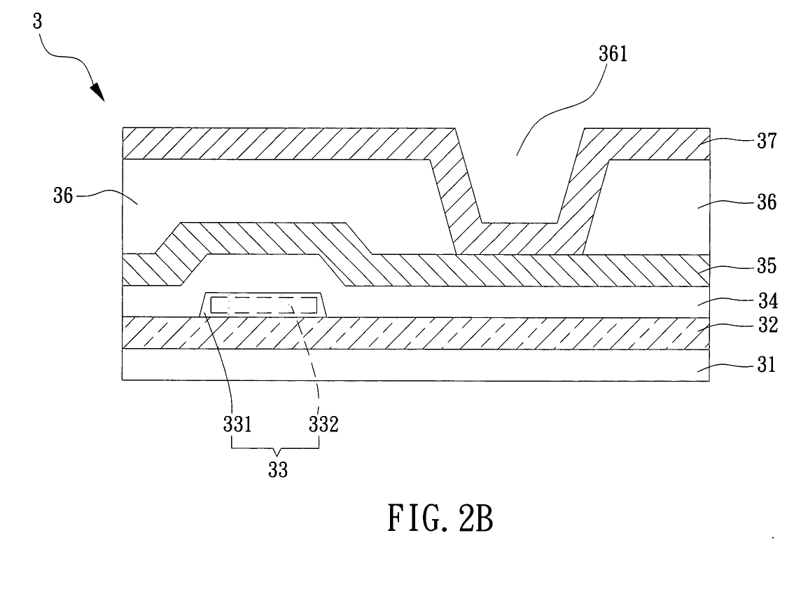

Referring to FIG. 2a, a cross-sectional view of an embodiment according to principles the invention is provided. In the figure illustrated, an apparatus of ion sensitive transistors 2 comprises: a glass substrate 21, a layer of buffer oxide 22, an active layer 23, a layer of gate oxide 24, a metal layer 25, a passivation layer 26 and a sensitive membrane 27. Said layer of buffer oxide 22 was formed on the surface of said glass substrate 21, wherein said layer of buffer oxide 22 formed on the surface of said glass substrate 21; said active layer 23, formed on the surface of said layer of buffer oxide 22, further including a pair of source/drains 231 separated from a channel region 232; said layer of gate oxide 24, formed on the surface of said active layer 23, further including contact holes 241 on said layer of gate oxide 24 set opposite to said pair of source/drains 231; said metal layer 25 formed on the surface of said layer of gate oxide 24 filling said contact hole 241 to from a pair of electrodes for said pair of source/drains 231; said passivation layer 26, formed on the surface of said metal layer 25, further including a probe area 261; and said sensitive membrane 27, formed on said passivation layer 26, covering said probe area 261. In this embodiment, the metal layer 25 covered on top of said channel region 232 is removed.

Referring to FIG. 2b, cross-sectional view of another embodiment according to principles the invention is provided. An apparatus of ion sensitive transistors 3 comprises: a glass substrate 31, a layer of buffer oxide 32, an active layer 33, a layer of gate oxide 34, a metal layer 35, a passivation layer 36 and a sensitive membrane 37. Said layer of buffer oxide 32 was formed on the surface of said glass substrate 31, wherein said layer of buffer oxide 32 formed on the surface of said glass substrate 31; said active layer 33, formed on the surface of said layer of buffer oxide 32, further including a pair of source/drains 331 separated from a channel region 332; said layer of gate oxide 34, formed on the surface of said active layer 33; said metal layer 35 formed on the surface of said layer of gate oxide 34; said passivation layer 36, formed on the surface of said metal layer 35, further including a probe area 361; and said sensitive membrane 37, formed on said passivation layer 36, covering said probe area 361. In this embodiment, the metal layer 35 covered on top of said channel region 332 is not removed and coupled with gate electrode and said probe area 361.

In the embodiments described above, said pair of source/drains 231, 331 are selected from the group consisting of N-type doping and P-type doping. Furthermore, said sensitive membrane 27, 37 can be formed in a different kind of material depending on the solution under test. For example, there has been disclosed using said sensitive membrane including SiO₂, SiNₓ, Al₂O₃, TiO₂, and TaOₓ to detect the hydrogen ions in the solution under test while the enzyme membrane is utilized to detect the consistency of glucose in a solution under test.

As to the operation of ion sensitive transistors, for instance, in the case of ion sensitive transistors utilized to detect glucose in a solution, when ion sensitive transistor is immersed in a test solution, the immobilized enzyme membrane reacts with the specific biological substance in the test solution. As a result, the ion concentration in the enzyme membrane will vary in proportion to the concentration of the specific biological substance in the test solution. The ion sensitive transistor, whereby the concentration of the specific biological substance can be measured, senses this above-mentioned variation of ion concentration. By means of the variation of the electrochemical potential, the conduction of ion sensitive transistor will be changed. Therefore, the change of the concentration of the hydrogen ions in the solution can be detected as that of the drain current of the transistor. Then the concentration of glucose can be known.

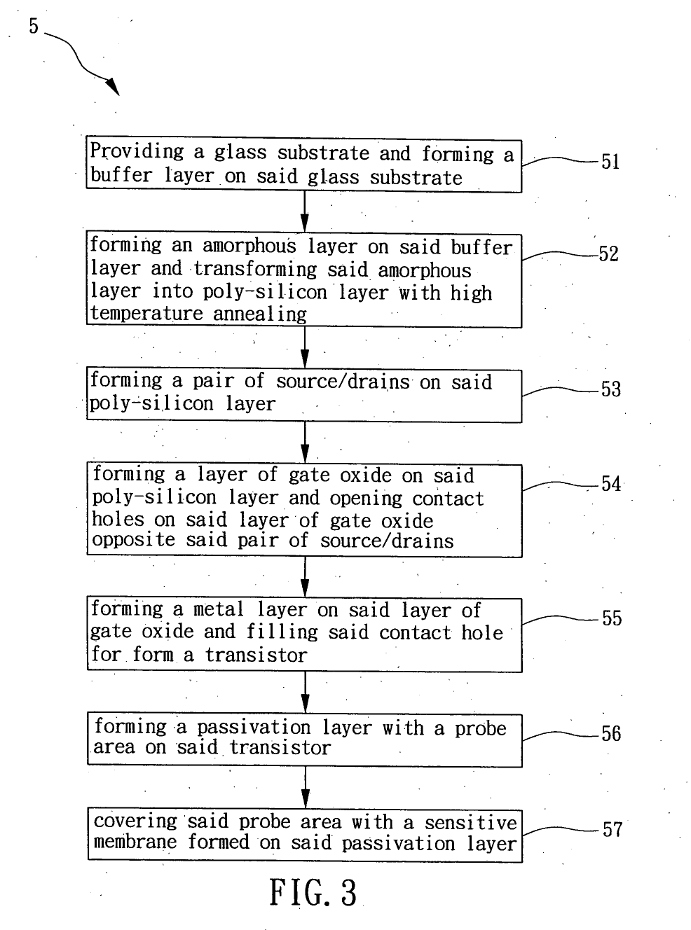

Referring to FIG. 3, a flow chart of the method to manufacture the ion sensitive thin film transistor according to the principles of the invention is provided. The method comprises the steps of:
Step 51: Providing a glass substrate and forming a buffer layer on said glass substrate;
Step 52: forming an amorphous layer on said buffer layer and transforming said amorphous layer into poly-silicon layer with high temperature annealing;
Step 53: forming a pair of source/drains on said poly-silicon layer;
Step 54: forming a layer of gate oxide on said poly-silicon layer and opening contact holes on said layer of gate oxide opposite said pair of source/drains;
Step 55: forming a metal layer on said layer of gate oxide and filling said contact hole for form a transistor;
Step 56: forming a passivation layer with a probe area on said transistor; and
Step 57: covering said probe area with a sensitive membrane formed on said passivation layer.

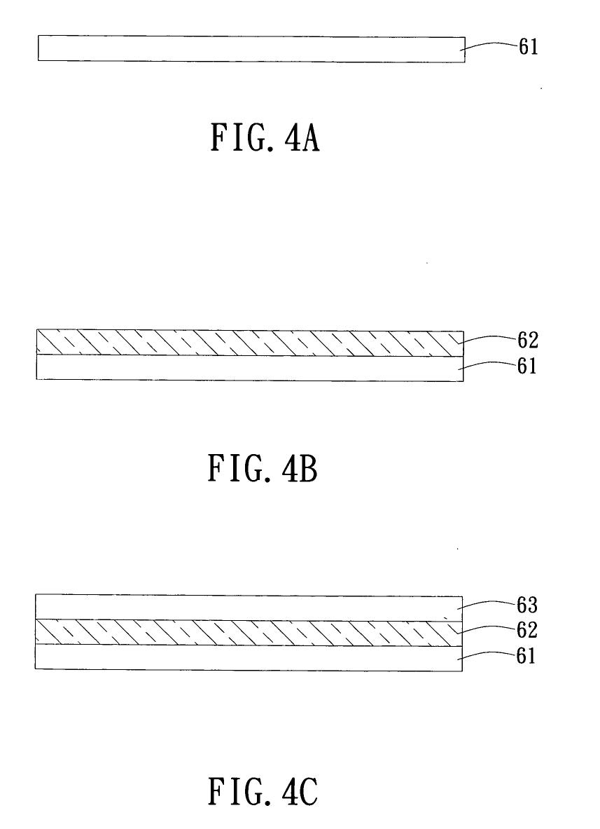

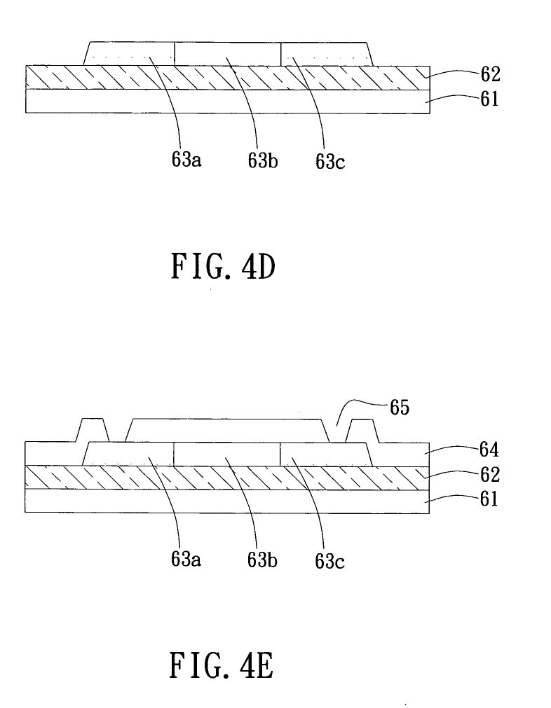

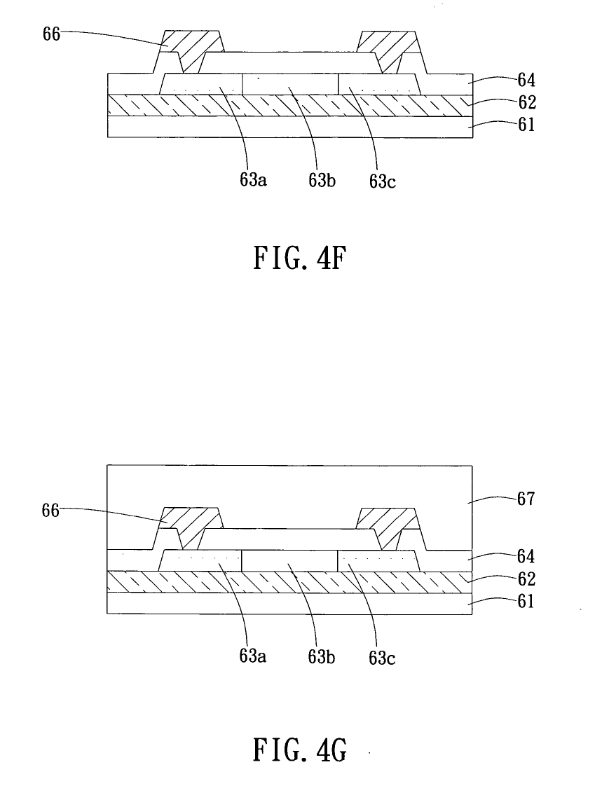

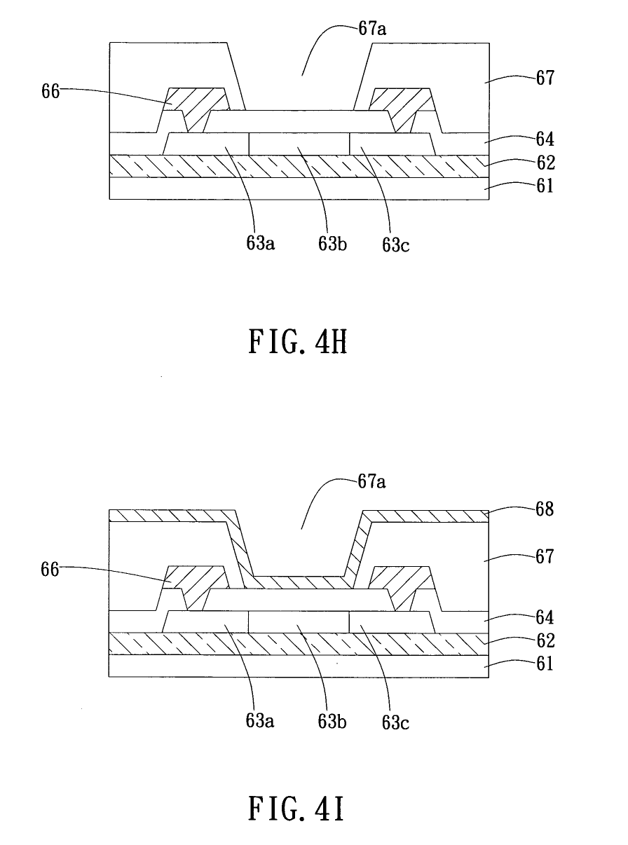

Please refer to the FIG. 4a through FIG. 4i for further comprehension. Those drawings illustrate the cross-sectional views illustrating the steps according to the method of the invention to manufacture ion sensitive thin film transistor.

For forming the ion sensitive thin film transistor, as shown in FIG. 4a, a glass substrate 61 is provided, and then, as shown in FIG. 4b, a layer of buffer oxide 62 was deposited to isolate the mobile ions, such as K⁺ or Na⁺, in said glass substrate 61. As shown in FIG. 4c, furthermore, a layer of amorphous silicon is deposited in a way of CVD on said layer of buffer oxide 62, then said amorphous silicon layer is transformed into poly-silicon layer 63 by way of high temperature annealing. Afterwards, as shown in FIG. 4d, it is patterned by the method of photolithography and then an ion implantation was utilized to define a region of source 63a and drain 63c, wherein the doping in the region can be selected from group consisting of N-type or P-type.

Please refer to FIG. 4e, after finishing the process of active layer, the layer of gate oxide 64 is deposited on the surface of said poly-silicon layer 63 and opening a contact hole 65 on said layer of gate oxide 64 opposite said source 63a and drains 63c. Afterwards, as shown in FIG. 4f, a metal layer 66 was formed on the layer of gate oxide 64, wherein said pair of contact holes 65 was filled with said metal layer 66 and then leading wires are bonded.

There are two ways to deal with surface above said channel region 63b, one is to remove said metal layer which is illustrated in FIG. 2a and the other is to retain said metal layer which is illustrated in FIG. 2b. As shown in FIG. 4g, while the stage of forming metal layer 66 is finished, it should deposit a thick layer of passivation 67 on the top surface of said metal layer 66 and then a probe area 67a is etched on said passivation layer 67 which is illustrated in FIG. 4h. Please refer to FIG. 4i; finally, a sensitive membrane 68 was formed on said passivation layer 67.

After the formation of ion sensitive transistors, conventionally, those transistors should be coupled with the other devices such as PCB and control circuits, to become an inspection apparatus. Consequently, it will induce a lot of cost and time consuming during production. Hence, the present invention provide an innovation method to integrate said ion sensitive transistors, peripheral control circuit devices and display panel altogether by way of LTPS technique to make tiny, lightly, and even cheap apparatus.

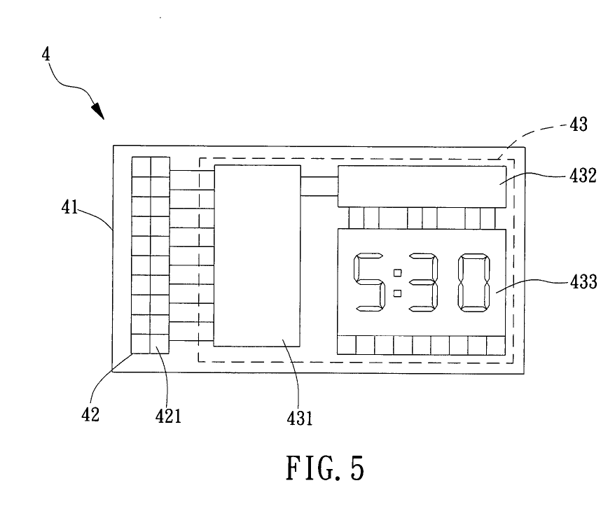

For more detail to understand what is described above, please refer to the FIG. 5, the illustration provides a schematic view to illustrate the apparatus comprising ion sensitive detector and signal processor with display, wherein said ion sensitive thin film transistor apparatus 4, comprises: a glass substrate 41, an ion detector 42, formed on said glass substrate 41, including a plurality of ion sensitive sensors 421, and a signal processor with display 43, formed on said glass 41, being coupled with said ion detector 421. The ion sensitive sensors 421 are possible to use the disclosure illustrated in FIG. 2a or the disclosed one illustrated in FIG. 2b.

The signal processor with display 43 further comprises: a circuit of signal processing 431, formed on said glass substrate 41, being coupled with said ion detector 421, a driver circuit 432, formed on said glass substrate 41, being coupled with said circuit of signal processing 431, and a display 433, formed on said glass substrate 41, being coupled with said driver circuit 432.

The illustration in FIG. 5 is the apparatus integrating in unity with tiny, light and thin characteristics for the purpose of portability and disposability.

While the present invention has been described and illustrated herein with reference to the preferred embodiment thereof, it will be understood by those skilled in the art that various changes in form and details may be made therein without departing from the spirit and the scope of the invention.

What is claimed is:

1. An ion sensitive thin film transistor apparatus, comprising:
a glass substrate;
an ion detector, formed on said glass substrate, including a plurality of ion sensitive sensors; and
a signal processor with display formed on said glass and coupled with said ion detector.

2. The apparatus as claimed of claim 1, wherein the said signal processor with display further comprising:
a circuit of signal processing, formed on said glass substrate and being coupled with said ion detector;
a driver circuit formed, on said glass substrate and being coupled with said circuit of signal processing; and
a display formed on said glass substrate and being coupled with said driver circuit.

3. The apparatus as claimed of claim 1, wherein the said ion detector further comprising:
a buffer layer formed on the surface of said glass substrate;
an active layer, formed on the surface of said buffer layer, further including a pair of source/drains separated from a channel region;
a layer of gate oxide, formed on the surface of said active layer, further including contact holes on said layer of gate oxide set opposite to said pair of source/drains;
a metal layer formed on the surface of said layer of gate oxide filling said contact hole to from a pair of electrodes for said pair of source/drains;
a passivation layer, formed on the surface of said metal layer, further including a probe area; and
a sensitive membrane, formed on said passivation layer, covering said probe area.

4. The apparatus as claimed of claim 3, wherein said buffer layer is substantially an oxide layer.

5. The apparatus as claimed of claim 3, wherein said pair of source/drains are selected from the group consisting of N-type doping and P-type doping.

6. The apparatus as claimed of claim 3, wherein said sensitive membrane is selected from the group consisting of enzyme membrane, SiO₂, oxide of silicon, Al₃O₂, TiO₂ and TaOₓ, oxide of tantalum.

7. The apparatus as claimed of claim 3, wherein said passivation layer is a kind of material with low-k dielectric.

8. The apparatus as claimed of claim 3, wherein the top of said channel region is selected from the group consisting of retaining said metal layer and removing said metal layer.

9. An ion sensitive thin film transistor, comprising:
a glass substrate;
a buffer layer formed on the surface of said glass substrate;
an active layer, formed on the surface of said buffer layer, further including a pair of source/drains separated from a channel region;
a layer of gate oxide, formed on the surface of said active layer, further including contact holes on said layer of gate oxide set opposite to said pair of source/drains;
a metal layer formed on the surface of said layer of gate oxide filling said contact hole to from a pair of electrodes for said pair of source/drains;
a passivation layer, formed on the surface of said metal layer, further including a probe area; and
a sensitive membrane, formed on said passivation layer, covering said probe area.

10. The apparatus as claimed of claim 9, wherein said buffer layer is a oxide layer.

11. The apparatus as claimed of claim 9, wherein said pair of source/drains are selected from the group consisting of N-type doping and P-type doping.

12. The apparatus as claimed of claim 9, wherein said sensitive membrane is selected from the group consisting of enzyme membrane, SiO₂, oxide of silicon, Al₃O₂, TiO₂ and TaOₓ, oxide of tantalum.

13. The apparatus as claimed of claim 9, wherein said passivation layer is a kind of material with low-k dielectric.

14. The apparatus as claimed of claim 9, wherein the top of said channel region is selected from the group consisting of retaining said metal layer and removing said metal layer.

15. A method of manufacturing an ion sensitive thin film transistor comprising the steps of:
(a) providing a glass substrate and forming a buffer layer on said glass substrate;
(b) forming an amorphous layer on said buffer layer and transforming said amorphous layer into poly-silicon layer with high temperature annealing;
(c) forming a pair of source/drains on said poly-silicon layer;
(d) forming a layer of gate oxide on said poly-silicon layer and opening contact holes on said layer of gate oxide opposite said pair of source/drains;
(e) forming a metal layer on said layer of gate oxide and filling said contact hole for form a transistor;
(f) forming a passivation layer with a probe area on said transistor; and
(g) covering said probe area with a sensitive membrane formed on said passivation layer.

16. The method as claimed of claim 15, wherein said buffer layer is a oxide layer.

17. The method as claimed of claim 15, wherein said pair of source/drains are selected from the group consisting of N-type doping and P-type doping.

18. The method as claimed of claim 15, wherein said pair of source/drains is separated from a channel region.

19. The method as claimed of claim 18, wherein the top of said channel region is selected from the group consisting of retaining said metal layer and removing said metal layer.
